(19) United States
(12) Patent Application Publication
(10) Pub. No.: US 2011/0297227 A1
(43) Pub. Date: Dec. 8, 2011

(54) HETERO SOLAR CELL AND METHOD FOR PRODUCING HETERO SOLAR CELLS

(75) Inventors: Damian Pysch, Freiburg (DE); Stefan Glunz, Freiburg (DE)

(73) Assignee: Fraunhofer-Gesellschaft zur Forderung der Angewandten Forschung E.V., Munchen (DE)

(21) Appl. No.: 13/062,010

(22) PCT Filed: Aug. 12, 2009
(86) PCT No.: PCT/EP2009/005855

§ 371 Date: May 25, 2011

(30) Foreign Application Priority Data
Sep. 3, 2008 (DE) 10 2008 045 522.9

(51) Int. Cl. H01L 31/0376; H01L 31/18

(52) U.S. Cl. 136/258; 438/96; 257/E31.047

(57) ABSTRACT

The invention relates to a hetero solar cell which comprises silicon, doped silicon layers and tunnel passivation layers. This is concluded by an indium-tin oxide layer on the front-side and by an aluminium layer on the rear-side. Furthermore, the invention relates to a method for producing hetero solar cells.

The invention relates to a hetero solar cell which comprises silicon, doped silicon layers and tunnel passivation layers. This is concluded by an indium-tin oxide layer on the front-side and by an aluminium layer on the rear-side. Furthermore, the invention relates to a method for producing hetero solar cells.

Wafer-based crystalline silicon solar cells having an emitter made of amorphous silicon (hetero solar cells) are commercially available. Monocrystalline silicon is used for this purpose as starting material and is n- or p-doped (M. Tanaka, et al., Jnp. J. Appl. Phys., Vol. 31 (1992), pp. 3518-3522 and M. Schmidt, et al., Thin Solid Films 515 (2007), p. 7475). Firstly a very thin (approx. 1 to 10 nm) intrinsic (undoped) amorphous silicon layer is applied on this towards the illuminated side. Thereafter, application of a likewise very thin (approx. 1 to 10 nm), doped amorphous silicon layer, the doping of which is oppositely to the basic doping, is effected. Finally, a conductive transparent oxide, such as e.g. indium-tin oxide (ITO) and thin metal contacts are applied. On the non-illuminated rear-side of the crystalline wafer, firstly a very thin (approx. 1 to 10 nm), intrinsic (undoped), amorphous silicon layer and subsequently a very thin (approx. 1 to 10 nm), doped, amorphous silicon layer, which is adapted to the basic doping, is applied. Finally, a metal layer is applied which serves for contacting the solar cell.

The amorphous silicon layers are at present produced by means of plasma-enhanced chemical vapour deposition (PECVD technology) and the conductive transparent oxide (ITO) is produced by means of sputtering technology.

The efficiency of the hetero silicon solar cell reacts very sensitively to the defect state density of the interface between crystalline silicon and the amorphous emitter (or intrinsic, amorphous silicon layer). The small defect density of the interface is at present produced mainly by a suitable pretreatment of the crystalline wafer (e.g. wet-chemically, such as in the case of H. Angermann, et al., Material Science and Engineering B, Vol. 73 (2000), p. 178) and by the intrinsic or doped amorphous silicon layer itself.

A further possibility for passivating an interface can be achieved by placing stationary charges as close as possible to the interface to be passivated (A. Aberle, et al., J. Appl. Phys. 71(9), (1992), p. 4422). This possibility is not exploited specifically in the current silicon hetero solar cell structures.

A further method, known from the state of the art, for producing hetero solar cells is the deposition of the amorphous layers by means of PECVD. As long as the surface has no uniform topography, a different quantity of the substance to be deposited is deposited on the peaks and in the valleys of the textured pyramids. This requires pretreatment of the textured pyramids (M. Tanaka, et al., Jnp. J. Appl. Phys., Vol. 31 (1992), pp. 3518-3522).

Starting herefrom, it is the object of the present invention to eliminate the disadvantages of the state of the art and to provide hetero solar cells which are substantially more robust with respect to high interface defect density and short circuits on the textured pyramid peaks and to enable faster processing.

This object is achieved by the hetero solar cell having the features of claim 1. Claim 17 relates to a method for producing hetero solar cells. Further advantageous embodiments are contained in the dependent claims.

According to the invention, a hetero solar cell is provided, which comprises an emitter which is disposed on the front-side surface of a crystalline, doped silicon wafer (c-Si layer) and is made of an amorphous silicon layer (a-Si layer) doped oppositely to the c-Si layer and also an ITO layer (indium-tin oxide layer) disposed thereon with front-side contact and a metallisation layer disposed on the rear-side surface, a tunnel passivation layer being applied at least between the front-side surface of the c-Si layer and the emitter layer.

Due to this construction, achieving high efficiency becomes substantially more robust. The latter is thereby dependent upon the layer thickness and also on the regularity of the layers.

The thickness of the tunnel passivation layer is preferably chosen such that a quantum-mechanical tunnel current flows. This applies in particular to passivation layers having a band gap E_{g}≧2 eV.

The hetero solar cell can have a tunnel passivation layer on the front-side and rear-side surface.

By using tunnel passivation layers, the previously common, complex precleaning processes of the wafers recede into the background. If necessary, they can even be completely dispensed with and thus enable faster production of hetero solar cells which in addition is more economical.

The materials of the tunnel passivation layer or insulating layer of the hetero solar cell itself are expediently selected from aluminium oxide, silicon oxide and/or silicon nitride. Preferably, a tunnel passivation layer is thereby made of aluminium oxide Al₂O₃, since this material has several advantages. The aluminium oxide layers have a very high density of incorporated, negative charges, an exceptionally good passivation quality is therefore produced. Furthermore, aluminium oxide can be deposited homogeneously by means of the atomic layer deposition method or similarly-operating PECVD methods on almost any surface topography. The growth rate on perpendicular sides is hereby equal to the growth rate on flat regions. Fixed charges can be incorporated subsequently (e.g. by means of ion implantation of Cs⁺ ions) in the tunnel passivation layer or insulating layer.

In a preferred embodiment, the thickness of the tunnel passivation layer made of aluminium oxide is between 0.1 and 10 nm since this layer thickness enables both a quantum-mechanical tunnelling of the charge carriers and passivation of the surfaces.

In the hetero solar cell according to the invention, the aluminium oxide layer Al₂O₃ (or other aluminium oxide stoichiometries), and also the insulating layer (e.g. SiOₓ), is deposited with subsequent incorporation of fixed charges (e.g. by ion implantation of Cs⁺ ions) both directly on the precleaned (possibly weakly precleaned or untreated) and textured front-side and on the reflection-optimised rear-side surface. The incorporated negative charges of the aluminium oxide layer thereby significantly enhance the passivation effect. Since aluminium oxide has a higher band gap than crystalline and amorphous silicon, the layer thickness thereof must be chosen to be as small as possible, on the one hand, in order to enable a quantum-mechanical tunnelling of the charge carriers through this layer and, on the other hand, have sufficient thickness so that the passivation effect is ensured. In order to fulfil both requirements, it is favourable to maintain a layer thickness in the one- to two-digit Angström range. Since the layer thickness can be adjusted very precisely for example by using atomic layer deposition technology (ALD) (or similarly-operating PECVD methods), high reproducibility is ensured. This layer can be incorporated either additionally in the system or replace the intrinsic, amorphous layer. By using ALD technology (or similarly-operating PECVD methods) uniform covering of the textured pyramids is also ensured at the same time.

The essential advantages of the hetero solar cell and also of the production method by using thin tunnel passivation layers (e.g. Al₂O₃) are:
a homogeneous covering of the textured pyramids
the requirements for precleaning of the crystalline wafer can be greatly reduced or possibly completely dispensed with
the requirement for as gentle a plasma deposition as possible can be possibly relaxed (e.g. Al₂O₃ ensures the passivation effect). Consequently, higher growth rates can be used which result in faster processing
an altogether substantially more robust method

In addition, it is possibly possible to dispense with the undoped (intrinsic) amorphous layer and hence to achieve shortening and simplification of the production process.

Hence, the efficiency of n- and/or p-type (basic wafer) hetero solar cells can be increased in total by the described use of tunnel layers.

Preferably, the emitter layer consists of an a-Si layer doped oppositely to the c-Si layer and an intrinsic silicon layer (i-Si layer).

The thickness of the a-Si layer doped oppositely to the c-Si layer is preferably between 1 and 10 nm. It is thus ensured that the layer is homogeneous. In addition, this layer thickness enables the construction of a hetero solar cell.

In a variant of the hetero solar cell, the chosen thickness of the i-Si layer is between 1 and 10 nm. The layer thickness of the undoped i-Si layer is kept hence as low as possible.

The intrinsic and also the amorphous silicon layer can serve in addition also for the passivation.

Preferably, an amorphous silicon layer doped equally to the c-Si layer is applied between the rear-side surface and the metallisation layer.

The thickness of this amorphous silicon layer, in an alternative embodiment of the hetero solar cell, is between 1 and 30 nm.

In a further embodiment, an intrinsic silicon layer is applied between the metallisation layer and the amorphous silicon layer which is applied on the rear-side surface and doped equally to the crystalline silicon layer.

The thickness of the intrinsic silicon layer is preferably between 1 and 10 nm.

The crystalline silicon layer is preferably n- or p-doped. The thickness of this layer is preferably between 20 and 2,000 μm.

In a further embodiment of the hetero solar cell, the amorphous silicon layer which is contained in the emitter layer and doped oppositely to the c-Si layer is n- or p-doped.

The amorphous silicon layer which is applied between the rear-side surface and the metallisation layer and is doped equally to the crystalline silicon layer can be n- or p-doped.

Furthermore, the invention relates to a method for producing the already described hetero solar cell.

The at least one tunnel passivation layer has been thereby deposited preferably by means of atomic layer deposition- or PECVD technology. This method of atomic layer deposition (or similarly-operating PECVD methods) effects homogeneous covering of the textured pyramids and reduces the requirements for precleaning of the crystalline wafer or makes this superfluous.

The tunnel passivation layer or insulating layer preferably consists of aluminium oxide, silicon oxide and/or silicon nitride or comprises this. It can also comprise Cs⁺ ions. Subsequently, fixed charges can be incorporated (e.g. by ion implantation of Cs⁺ ions) in the tunnel passivation layer or insulating layer. Such layers enable quantum-mechanical tunnelling of the charge carriers through these, and also passivation. Since the atomic layer deposition technology or the similarly-operating PECVD method can be adjusted very precisely, exact deposition of the layers can be ensured. In addition, the requirement for a gentle plasma deposition of the amorphous silicon layers can be relaxed since these tunnel layers ensure the passivation effect. Consequently, higher growth rates can be used and faster processing is thus made possible.

A further method variant is characterised in that the at least one tunnel passivation layer comprises aluminium oxide, silicon oxide and/or silicon nitride and/or consists thereof. The aluminium oxide can hereby also have stoichiometries other than Al₂O₃. Furthermore, fixed charges can be incorporated after deposition of an insulator (e.g. SiOₓ) (e.g. by ion implantation of Cs⁺ ions).

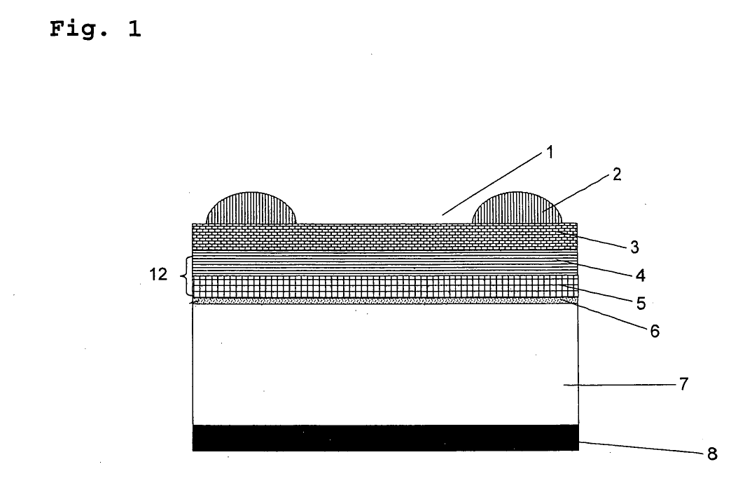

The subject according to the application is intended to be explained in more detail with reference to the following FIGS. 1 to 3, without wishing to restrict said subject to the special embodiments shown here. The subject according to the invention and also the method apply to any surfaces of the crystalline wafer (preferably textured pyramids).

FIG. 1 shows the construction of a hetero solar cell having a front-side tunnel passivation layer and emitter layer;

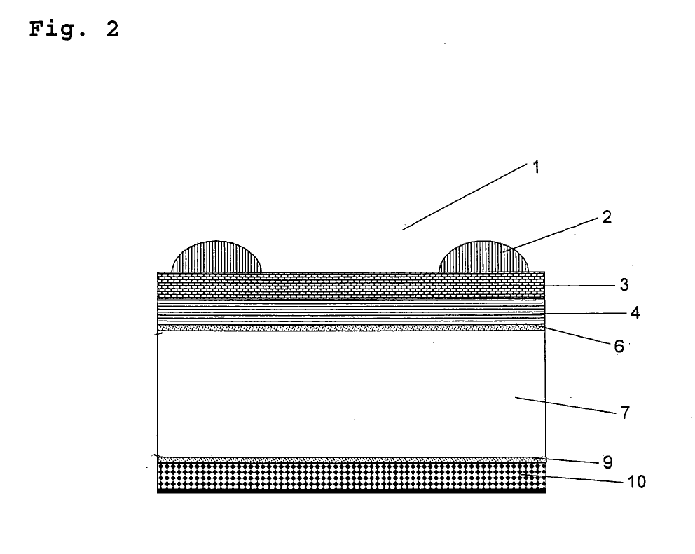

FIG. 2 shows the construction of a hetero solar cell having a front-side tunnel passivation layer and emitter layer and additional rear-side coating including tunnel passivation layer;

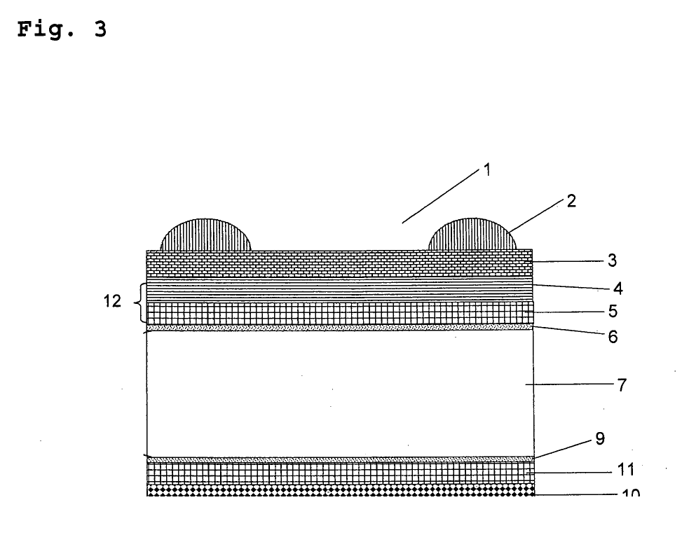

FIG. 3 shows the construction of a hetero solar cell having a front-side tunnel passivation layer and emitter layer and an additional rear-side coating including tunnel passivation layer which comprises a further intrinsic layer.

In FIG. 1, an embodiment of the hetero solar cell 1 is represented, in which an emitter layer 12 is disposed on the crystalline front-side surface of the Si wafer 7. The crystalline silicon layer 7 is n-doped and has a thickness of approx. 200 μm. By means of atomic layer deposition, the tunnel passivation layer (e.g. aluminium oxide layer (Al₂O₃) 6 which has a thickness of 0.1 to 10 nm, is deposited by means of ALD or PECVD. Subsequently, the intrinsic amorphous silicon layer 5 which is not doped is applied. This has a thickness of 1 to 10 nm. The p-doped amorphous silicon layer 4 which is orientated towards the front-side or towards the irradiated side has a thickness of 1 to 10 nm. The layers 4 and 5 thereby form the emitter layer 12. A conductive, transparent oxide layer (ITO) 3 is applied thereupon by means of sputtering technology and with a layer thickness of approx. 80 nm (dependent upon the refractive index of the ITO). An aluminium layer 8 is applied on the rear-side of the hetero solar cell. This serves, as also the front-side contacts 2 of the hetero solar cell, for contacting.

FIG. 2 shows the layer construction of a planar silicon hetero solar cell 1 having a front-side emitter layer and an additional rear-side coating. A tunnel passivation layer (e.g. aluminium oxide layer) 6 or 9 is applied here on both sides of the crystalline n-doped silicon layer 7, which has a thickness of 200 μm, by means of ALD or the similarly-operating PECVD method. These (aluminium oxide) layers have a thickness of 0.1 to 10 nm. There follows on the front-side of the hetero solar cell a p-doped amorphous silicon layer 4 with a thickness of 1 to 10 nm, as well as an ITO layer 3, which has a thickness of 80 nm. On the front-side, the solar cell is provided with metal contacts 2. The rear-side of the hetero solar cell 1 forms a concluding aluminium layer 8. An amorphous n-doped silicon layer 10 is inserted between the aluminium layer 8 and the aluminium oxide layer 9. Said silicon layer has a thickness of 1 to 30 nm.

FIG. 3 shows a hetero solar cell 1 having a front-side emitter layer 12 and an additional rear-side coating which comprises a further intrinsic layer 11. This hetero solar cell is constructed from an aluminium layer 8. There follows as next layer a 1 to 30 nm thick amorphous n-doped silicon layer 10. On this, an intrinsic amorphous silicon layer 11 with a thickness of 1 to 10 nm is applied. A tunnel passivation layer 9 is contained between the n- or p-doped crystalline silicon layer 7 and the amorphous intrinsic silicon layer 11. Said tunnel passivation layer has a thickness of 0.1 to 10 nm. On the front-side of the 200 nm thick crystalline n-doped silicon layer 7, a further tunnel passivation layer 6 with a thickness of 0.1 to 10 nm is applied. Following thereon is an intrinsic amorphous silicon layer 5 with a layer thickness of 1 to 10 nm. Between the ITO layer 3 which has a thickness of approx. 80 nm and the intrinsic amorphous silicon layer 5, a p-doped amorphous silicon layer 4 with a layer thickness of 1 to 10 nm is applied. Metal contacts 2 are fitted on the front-side of the hetero solar cell 1.

### EMBODIMENT 1

The amorphous silicon layers are produced by means of plasma-enhanced chemical vapour deposition (PECVD). The generator power and frequency hereby used is 2 to 200 W and 13.56 MHz up to 2 GHz. The gas flows are in the range of 1 to 100 sccm for silane SiH₄, 0 to 100 sccm for hydrogen H₂, 1 to 50 sccm for the doping by means of diborane B₂H₆ and for phosphine PH₃ (dissolved in 1-5% H₂). The temperature of the substrate is between 100 and 300° C. The prevailing pressure in the PECVD plant during the production process of the hetero solar cell is between 10¹ and 10⁻⁵ mbar (as a function of the plasma source which is used). The basic pressure should be chosen to be less than 10⁻⁵ mbar. The electrode spacing, in the case of a parallel plate reactor, is between 0.5 and 5 cm. The process duration results from the deposition rate and the desired layer thickness and is in the range of 5 to 60 seconds. The tunnel passivation layer (e.g. Al₂O₃) is deposited by means of atomic layer deposition (ALD) or similarly-operating PECVD processes. These aluminium oxide layers are produced in two cycles. Cycle 1 comprises deposition of radicalised trimethyl aluminium and cycle 2 the oxidation of the layers with O₂. The deposited trimethyl aluminium is radicalised by means of a plasma source, comparable to that already described, which is situated relatively far away from the substrate (5 to 50 cm). The substrate temperature is hereby room temperature to 350° C.

What is claimed is:

1. A hetero solar cell comprising:
an emitter which is disposed on the front-side surface of a crystalline, doped silicon wafer (c-Si layer) and is made of an amorphous silicon layer (a-Si layer) doped oppositely to the c-Si layer and also an ITO layer disposed thereon with front-side contact and a metallisation layer disposed on the rear-side surface,
wherein a tunnel passivation layer is applied at least between the front-side surface of the c-Si layer and the emitter layer.

2. The hetero solar cell according to claim 1, wherein a tunnel passivation layer is applied on the front-side and rear-side surface.

3. The hetero solar cell according to claim 1, wherein the thickness of the tunnel passivation layer is chosen such that a quantum-mechanical tunnel current flows.

4. The hetero solar cell according to claim 1, wherein the tunnel passivation layer is comprised of aluminium oxide, silicon oxide and/or silicon nitride.

5. The hetero solar cell according to claim 4, wherein ions are implanted in the tunnel passivation layer.

6. The hetero solar cell according to claim 4, wherein the thickness of the tunnel passivation layer made of aluminium oxide is between 0.1 and 10 nm.

7. The hetero solar cell according to claim 1, wherein the emitter layer comprises an a-Si layer doped oppositely to the c-Si layer and an intrinsic silicon layer (i-Si layer).

8. The hetero solar cell according to claim 7, wherein the thickness of the a-Si layer is between 1 and 10 nm.

9. The hetero solar cell according to claim 7, wherein the thickness of the i-Si layer is between 1 and 10 nm.

10. The hetero solar cell according to claim 1, wherein an a-Si layer doped equally to the c-Si layer is applied between the rear-side surface and the metallisation layer.

11. The hetero solar cell according to claim 10, wherein the thickness of the a-Si layer is between 1 and 30 nm.

12. The hetero solar cell according to claim 10, wherein an intrinsic silicon (i-Si layer) layer is applied between the metallisation layer and the a-Si layer which is applied on the rear-side surface and doped equally to the c-Si layer.

13. The hetero solar cell according to claim 12, wherein the thickness of the i-Si layer is between 1 and 10 nm.

14. The hetero solar cell according to claim 1, wherein the c-Si layer is n- or p-doped.

15. The hetero solar cell according to claim 1, wherein the thickness of the c-Si layer is between 20 and 2,000 μm.

16. The hetero solar cell according to claim 7, wherein the a-Si layer which is contained in the emitter layer and doped oppositely to the c-Si layer is n- or p-doped.

17. The hetero solar cell according to claim 10, wherein the a-Si layer which is applied between the rear-side surface and the metallisation layer and is doped equally to the c-Si layer is n- or p-doped.

18. A method for producing a hetero solar cell comprising:
disposing an emitter on a front side surface of a crystalline, doped silicon wafer (c-Si layer), wherein the emitter includes an amorphous silicon layer (a-Si layer) doped oppositely to the c-Si layer and also an ITO layer disposed thereon with front-side contact and a metallisation layer disposed on the rear-side surface; and
applying a tunnel passivation layer at least between the front-side surface of the c-Si layer and the emitter layer, wherein the at least one tunnel passivation layer is deposited by means of atomic layer deposition or similarly-operating PECVD technology.

19. The method for producing a hetero solar cell according to claim 18, wherein an aluminium oxide, silicon oxide and/or silicon nitride layer comprised of Cs⁺ ions is deposited as the tunnel passivation layer.
